(19) United States
(12) Patent Application Publication
(10) Pub. No.: US 2013/0095649 A1
(43) Pub. Date: Apr. 18, 2013

(54) Chemical Bath Replenishment

(71) Applicants: Tien-Jen Cheng, Bedford, NY (US); John Anthony Fitzsimmons, Poughkeepsie, NY (US); David E. Speed, Newtown, CT (US); Keith Kwong Hon Wong, Wappingers Falls, NY (US)

(72) Inventors: Tien-Jen Cheng, Bedford, NY (US); John Anthony Fitzsimmons, Poughkeepsie, NY (US); David E. Speed, Newtown, CT (US); Keith Kwong Hon Wong, Wappingers Falls, NY (US)

(73) Assignee: INTERNATIONAL BUSINESS MACHINES CORPORATION, Armonk, NY (US)

(21) Appl. No.: 13/274,413

(22) Filed: Oct. 17, 2011

(51) Int. Cl. H01L 21/3205; C25D 17/00

(52) U.S. Cl. 438/597; 204/233; 204/234; 257/E21.295

(57) ABSTRACT

Ions depleted from a chemical bath by a reaction such as plating are continually replenished by production and moving of ions through selectively permeable membranes while isolating potential contaminant ions from the chemical bath.

### FIELD OF THE INVENTION

The present invention generally relates to replenishment of materials in a chemical bath to maintain desired concentrations of materials as they are removed or consumed during semiconductor wafer processing and, more specifically, to material deposition processes and adjustment of pH in a chemical bath by in-situ hydroxyl ion generation, either alone or in combination with generation of other required ions such as metal in an electroplating or electroless plating process.

### BACKGROUND OF THE INVENTION

The desire for higher levels of performance from semiconductor integrated circuits has led to many highly sophisticated device designs and methods for their manufacture, even when materials presenting particular problems have been required to produce significant performance improvements. For example, for many years, aluminum was and continues to be used for connecting elements such as transistors and capacitors on integrated circuit chips even though other materials such as copper, silver and gold could provide lower bulk resistance. Gold and silver are soft and subject to damage as well as being expensive. Copper has presented many problems involving both chemical and mechanical interactions with other materials such as relatively poor adhesion to semiconductor materials, low solubility of desirable alloying materials in copper, attraction of contaminants and causing damage to some exotic materials such as dielectric materials having particularly high dielectric constants.

Nevertheless, the capability of the higher bulk conductivity of copper to reduce signal propagation time to allow integrated circuit operation at significantly higher clock speeds has led to solutions to a sufficient number of these problems that copper is currently used for some, if not all, wiring levels in high performance integrated circuits. For integrated circuit manufacture, copper (among other materials) is preferably applied by electroplating from a chemical bath in which the wafer is immersed. Completed copper wiring structures are then preferably capped to prevent other materials from reacting with the copper and damaging or otherwise compromising the copper structures and their performance. A preferred capping material is cobalt which is preferably applied by an electroless plating process.

In a chemical bath during electroless plating or electroplating, the plating bath chemistry is continually changing, principally by depletion of the material being deposited or otherwise consumed in the reaction. For plating of cobalt (Co), the cobalt reacts with tungsten and phosphorus in the solution and is deposited as a mixture of phosphides of cobalt and tungsten (CoWP). The chemical reactions involved in the electroless plating process also depletes hydroxyl ions (OH⁻) from the solution to complete the reaction with the hypophosphite which is a reducer used in the plating process. Therefore, hydroxyl ions are also depleted during the cobalt plating process. The reactions are:

2H₂PO₂⁻+2OH⁻-->2H₂PO₃⁻+H₂+2e⁻

Co⁺²+2e⁻-->Co(s)

The depletion of the hydroxyl ion also changes the pH of the chemical bath which should remain slightly alkaline (usually pH=8.5) for these reactions and for the plating to proceed normally and predictably. Therefore, Co⁺² and OH⁻ must be constantly replenished to maintain the concentrations of these and other materials within more or less closely specified set points during the plating reaction process. Similar requirements may be presented by other chemical reactions that may or may not involve processing of semiconductor wafers.

Normally, electroless plating baths for general plating applications are injected with potassium hydroxide (KOH) or sodium hydroxide (NaOH) as needed in order to replenish the hydroxyl ions. However, for semiconductor device manufacture, sodium and potassium are prohibited due to the possibility of contamination damage to the device since sodium and potassium ions are highly reactive and tend to diffuse into semiconductor materials where they may cause changes in electrical properties, much in the manner of a dopant. Hydroxyl ions can also be replenished by using tetramethylammonium hydroxide (TMAH) but questions of safety have recently arisen in regard to human exposure to TMAH or analog of TMAH.

### SUMMARY OF THE INVENTION

It is therefore an object of the present invention to provide an apparatus and method for continuous or periodic replenishment of materials in a plating bath to maintain a substantially constant bath chemistry in a fully controllable fashion without introducing sodium, potassium or TMAH to the bath.

It is another object of the invention to provide an apparatus and method integrating mature membrane technology with one or more electrochemical reaction processes for replenishment of reactant species in a chemical bath.

It is a further object of the invention to provide a method of adjusting pH or maintaining a constant pH in a chemical bath during a chemical reaction in which hydroxyl ions are consumed.

In order to accomplish these and other objects of the invention, a method of providing reactant ion species for a chemical reaction is provided comprising steps of dissociating a compound into a first ion and a second ion in a solution in a first compartment of a replenishment vessel by passing a current through the solution, splitting water into a proton and a hydroxyl ion in a membrane defining said first compartment and passing the first ion or the hydroxyl ion to a second compartment of the reaction vessel through a selectively permeable membrane which isolates the second ion in the first compartment to form a chemical bath.

In accordance with another aspect of the invention an apparatus for replenishing a chemical bath is provided comprising an anode, a cathode, a selectively permeable membrane separating a cathode rinse compartment containing a first solution from a chemical bath compartment containing a chemical bath solution, and a power supply for passing a current between the anode and the cathode through the first solution, the selectively permeable membrane and the chemical bath solution, the current causing electromigration of selected ions to said chemical bath solution while isolating other ions in the first solution from the chemical bath solution.

### BRIEF DESCRIPTION OF THE DRAWINGS

The foregoing and other objects, aspects and advantages will be better understood from the following detailed description of a preferred embodiment of the invention with reference to the drawings, in which:

FIG. 1 is a schematic diagram of a chemical bath replenishment process in accordance with the invention as applied to the electroless plating of cobalt, and

FIG. 2 is a schematic depiction of an exemplary embodiment of apparatus in accordance with the invention for electroless plating of cobalt and replenishment of hydroxyl ions from KOH while isolating potassium from the plating process.

### DETAILED DESCRIPTION OF A PREFERRED EMBODIMENT OF THE INVENTION

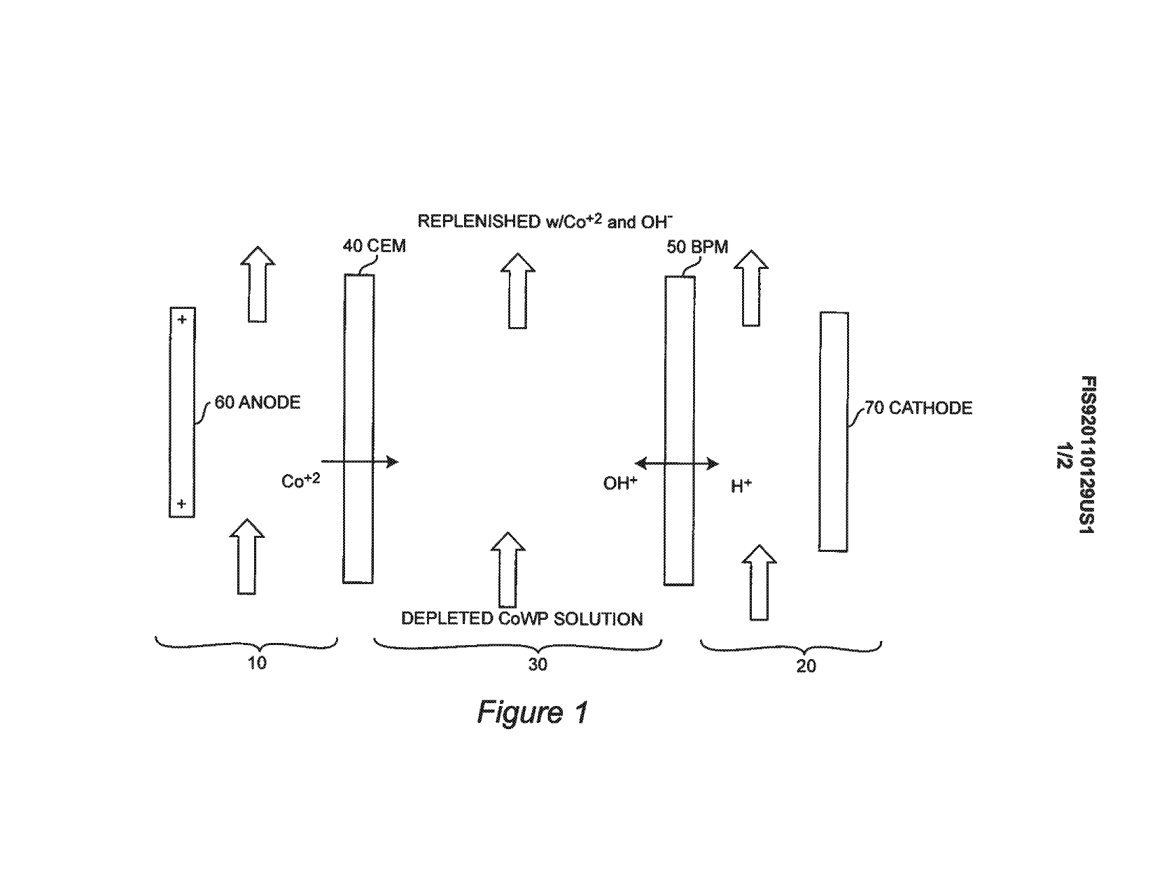

Referring now to the drawings, and more particularly to FIG. 1, there is shown, in schematic form, electrochemical reactions which provide replenishment of materials consumed in an exemplary electroless plating process for cobalt. It should be understood that while the invention will be discussed in terms of an application of the invention to the electroless plating of cobalt in which the invention has particularly valuable utility, the invention is fully applicable to any process involving the replenishment of materials in a solution where some materials for replenishment are preferably derived from substances which include constituents that must be (or are desirably) kept separate from the process that consumes materials that are replenished or, for that matter, any process involving a chemical bath which can benefit from having substantially constant bath chemistry while materials in the bath are being consumed by the process or in which pH must be adjusted or remain substantially constant by injection of hydroxyl ions and, particularly, where the hydroxyl ions are preferably derived from chemicals which may be toxic or contain materials which may potentially constitute a contaminant.

In accordance with its most basic principles, the purpose of the invention is to utilize a specialized electrodialysis system to replenish and modulate the hydroxide and exemplary cobalt concentration in the reaction or plating solution. The particular advantage of this system, particularly for semiconductor wafer processing, is that the hydroxyl ion is generated in-situ, which avoids the necessity of continual addition of a hydroxide base. In particular, the method and apparatus in accordance with the invention mitigates the need to use TMAH or metal hydroxides such as sodium hydroxide (NaOH) or potassium hydroxide (KOH), all of which are undesirable due to toxicity or potential influence on semiconductor device function.

Electrodialysis is an electrically driven membrane separation process. When a DC power supply is energized to supply a voltage and current between an anode and a cathode which are located at opposite ends of a membrane stack, the movement of cations toward the anode and anions toward the cathode is induced. At the cathode, there is an electrochemical reaction that results in the reduction of water into a hydroxyl ion and hydrogen gas. At the anode, there is an electrochemical reaction that results in the anodic dissolution of the anode solid (e.g. cobalt). Thus, in the exemplary cobalt plating process the anode comprises cobalt and the anodic dissolution serves as a source of dissolved cobalt ions and serves to replenish cobalt in the plating bath. However, replenishment of cobalt or other material, while appropriate and convenient for the exemplary cobalt plating process, is not necessary to the operation of the invention and the replenishment of hydroxyl ions in accordance with the most basic principles of the invention. That is, if the anode comprises more inert material(s), the replenishment of hydroxyl ions can still be efficiently provided without requirement for addition of undesirable hydroxide materials while replenishment of cobalt or any other reactant material can be accomplished by addition of a material containing the required material to be replenished.

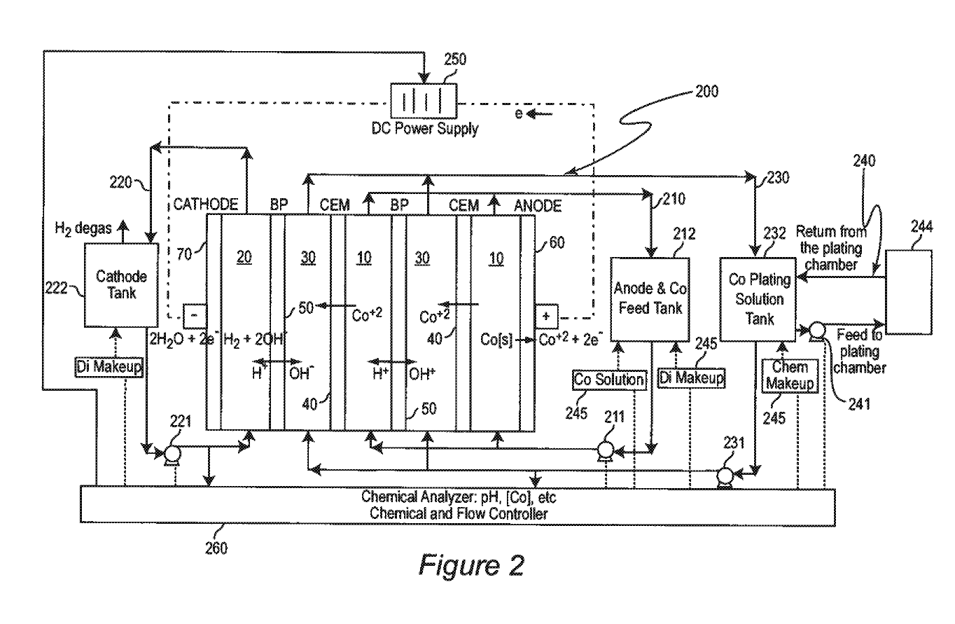

FIG. 1 depicts three compartments including two compartments 10, 20 separated from a reaction/replenishment compartment 30 by selectively permeable membranes 40, 50 which allow only selected ions to pass through to the reaction/replenishment compartment. It should be noted that while a plating or other reaction process could be performed in compartment 30, it is preferred for uniformity of processing to perform the plating or other reaction process in a separate chamber and to use chamber 30 only for replenishment of some or all of the dissolved species which are depleted during the plating or other reaction process as will be more fully described below with reference to FIG. 2. Therefore, compartment 30 will be referred to hereinafter simply as a replenishment compartment. This combination of compartments separated by membranes (which may include more or fewer compartments and/or membranes) is sometimes referred to as a cell stack or membrane stack system. Specifically, for the exemplary process of electroless plating of cobalt, cation exchange membrane (CEM) 40 will pass only cobalt ions developed in the first compartment 10 and bipolar membrane (BPM) 50 can be visualized as passing only (bipolar) hydroxyl ions and citrate ions developed in the second chamber 20 while containing all potassium (or sodium) ions within the second compartment 20 and isolated from the semiconductor wafer on which cobalt is plated in the replenishment compartment 30.

More specifically, without wishing to be held to any particular theory of the operation of a bipolar membrane during electrodialysis, it appears that the bipolar membrane, itself, which comprises a cation exchange layer and an anion exchange layer, when operated under a reverse potential bias, serves as a source of the hydroxyl or hydroxide anion OH⁻ and the dissolved proton H⁺. The bipolar membrane (BPM) produces these ions by dissociating the water that is available within the compartments. The ability of a BPM to dissociate water under an applied electropotential is a known but unexplained phenomenon and is commonly referred to as splitting water (as distinct from the well-known dissociation of water into hydrogen and oxygen gases by anodic and cathodic reactions where no BPM is present). Although a hydroxyl ion and a proton are generated within the BPM which serves as a source of these ions to the adjacent respective compartment (e.g. on opposite sides of the BPM), these ions do not appear to transport through the BPM.

Thus, the replenishment compartment 30 contains a solution of a mixture of chemicals suitable for electroless plating of cobalt on copper and, in solution, the materials may be in ionized form or neutral molecules which may be reaction products. For electroless plating of cobalt on copper, for example, the solution in the third compartment 30 will include anions, cations and neutral/reaction product constituents as listed in the following table (also included in FIG. 1):

| Cations | Anions | Neutral |
|---|---|---|
| Co⁺², Cu⁺² | C₆O₇H₆⁻² | |
| H⁺, (CH₃)₄N | WO₄⁻² | ((CH₃)₄N)₂WO₄ |
| H⁺ | H₂PO₂⁻, H₂PO₃⁻ | H₃PO₂ |
| (CH₃)₄N⁺ | H₃BO₄⁻ | (CH₃)₂NH*BH₃ or |
| | | C₄H₂O*BH₂, BH₃, |
| | | H₂BO₃ |
| (CH₃)₂NH₂⁺ | OH⁻ | (CH₃)₂NH |
| H⁺ | H₂BO₄⁻ | H₂BO₃ |
| (CH₃)₄N⁺ | OH⁻ | |
| H⁺ | OH⁻ | H₂O |

It should be understood that the above table lists only the anions, cations and materials or reaction products that are important to the exemplary cobalt plating process and which are in solution in replenishment compartment 30. Thus the neutral cobalt species is, for example, omitted from line 1 of the above table.

The chemical make-up in solution in compartments 10 and 20 are very much more simple. Compartment 10 contains a dilute solution of cobalt citrate as a source for cobalt ions. Compartment 20 contains a dilute solution of alkaline potassium citrate as a source for hydroxyl ions and citrate ions. Consumption of citrate and tungsten is very small in the exemplary cobalt plating process and can be adjusted independently of the hydroxyl ion (and cobalt ion) replenishment in accordance with the invention. The cobalt citrate and potassium citrate can source the cobalt and hydroxyl ions through an electrochemical reaction driven by passing a current through at least the compartments respectively including anode 60 and cathode 70 even though this electrochemical reaction is not otherwise involved in the electroless plating process. it should be understood the in electrodialysis, the cation and anion migration is driven by the applied electrical potential across the anode and cathode and through all membranes intervening between the anode and cathode.

The cobalt citrate and potassium citrate can be replenished as needed and it is preferred to provide for some circulation in compartments 10 and 20 both to distribute the replenishment materials to be substantially homogeneous throughout the compartment as well as to assure circulation over the anode and cathode where the electrochemical reaction takes place and the cobalt and hydroxyl ions are respectively produced/evolved and to circulate ions within compartment 30 such that they are evenly distributed over the surface on which cobalt is to be deposited as schematically indicated by arrows in each compartment. In practice, it is preferred to provide for circulation through each compartment, preferably by recirculation, with monitoring of the conditions and chemical make-up of the respective solutions being recirculated and to use a flow-through mesh or the like at the inlet of each compartment to create turbulence within the compartments for mixing and/or contact with the anode and cathode and to promote good mass transfer at the membrane surface.

Referring now to FIG. 2, an apparatus in accordance with the invention as applied to the exemplary process of the electroless plating of cobalt will now be described. For convenience of illustration, the order of compartments 10, 20 and 30 shown in FIG. 1 are reversed left-to-right in FIG. 2. Also, it is preferred for producing more uniform results at higher throughput, to multiply compartments 10 and 30 and to arrange them in alternating sequence. That is, while five compartments are shown in FIG. 2 and more or fewer compartments could be provided, the cell or membrane remains preferably divided into three flow compartments as shown in FIG. 1 with compartments 10 and 30 being divided into two or more compartments each, bounded on one side by a CEM 40 and on the other side by a BPM 50. Each compartment or group of compartments of similar chemical bath content (e.g. each of the three flow compartments referred to as a cathode rinse compartment 10, an anode compartment 20, preferably also providing cobalt ion feed, and a cobalt plating solution compartment 30, however compartments 10 and 30 may be further divided) is provided with an independent solution recirculation system 210, 220, 230 with respective pumps 211, 221, 231 and tanks 212, 222, 232 which serve to allow the respective solutions to be mixed and their homogeneities improved for analysis and control of solute concentrations. The cobalt plating solution compartment(s) are bordered by a cation permeable CEM 40 and a cobalt ion feed compartment on the cathode side of the cell and a bipolar permeable (BP) BPM 50 on the anode side of the cell. (When flow compartments 10 and 30 are divided as shown in FIG. 2, it is irrelevant to the practice of the invention whether or not BPM 50 is permeable to cations (e.g. Co⁺²) in view of the mixing of cation-containing solutions in recirculation path 230.) The cell stack system is preferably configured in a plate and frame configuration.

As is preferred and alluded to above, an additional circulation system including pump 241 is also provided to circulate the continually replenished chemical bath (e.g. plating solution) to a separate reaction chamber 244 of a manufacturing tool. A replenishment chamber 200 is provided to include compartments 10, 20 and 30, as separated by selective membranes 40 and 50, anode 60 and cathode 70 arranged in a cell stack as discussed above. The plating solution from the manufacturing tool which has been depleted of hydroxyl and metal ions is fed to compartment(s) 30 of the electrodialysis system replenishment tank 200 which adds hydroxyl and metal ions to replenish the plating solution with such ions to a desired concentration set point.

The concentrations of hydroxyl ions, metal ions and other constituents of the plating or other chemical reaction process are monitored by a chemical analyzers 245. Based on the detected concentrations and pH of the respective solutions in tanks 212, 222, 232 of flow paths 210, 220, 230, which are provided to programmable controller 260. Programmable controller functions to control the flow rate in recirculation paths 210, 220, 230 of the electrodialysis (ED) system 200 and the voltage/current applied from power supply 250 to achieve the desired set point concentrations in the plating solution as well as to control the addition of deionized (DI) water to replace the water that was dissociated in membranes 50 to supply hydroxyl ions and the degassing of hydrogen from the fluid in the cathode rinse flow compartment 20 and addition of other chemical constituents as necessary to maintain the composition of the chemical bath within user specified set point tolerances. Temperature, pressure, pH, conductivity and other physical parameters that can affect either or both of the reaction (e.g. CoWP plating) and chemical bath replenishment processes are also preferably monitored and controlled.

Tanks 212, 222 and 232 preferably hold a substantial volumes of respective solutions and serve to buffer any changes in chemical concentrations such that the chemical concentrations, particularly the chemical bath (e.g. CoWP plating solution_cannot vary rapidly. The CoWP tank 232 is also a convenient point to make adjustments in the chemical composition of the CoWP effluent which can be performed in a conventional manner such as removal of excess citrate ions and/or H₂PO₃ and/or replenishment of phosphorus and/or H₂PO₂. Flow controllers and/or pumps 211. 221 and 231 control the level of CoWP effluent in tank 232 as well as optimizing the flow rate for the plating process.

In operation for the exemplary plating of cobalt, the apparatus of FIG. 2 establishes flow in all three compartments depending on the results of analyzing the plating solution flowing through the replenishment compartment 30 where metal and hydroxyl ions are replenished in the depleted solution as the depleted solution flows past membranes 40 and 50 and thus recirculates dilute cobalt citrate in compartment 10, dilute potassium hydroxide (or sodium hydroxide) in compartment 20 and a solution with the chemistry summarized in the above table as well as controlling the addition of deionized water and cobalt citrate or potassium citrate to compartments 10 and 20 and deionized water and other chemicals that can be replenished in known ways to compartment 30 so that electroless plating can proceed in the normal manner but with the concentrations of cobalt and hydroxyl ions much more closely controlled and uniform in concentration than has previously been possible. Concurrently, the apparatus of FIG. 2 performs an electrochemical reaction to develop cobalt and hydroxyl ions which are fed to compartment 30 through selective membranes 40, 50 which can isolate materials that may otherwise be detrimental to the object on which the electroless plating is preformed.

It should be appreciated that the current requirements for the electrochemical process are very modest, at least for the exemplary electroless plating of cobalt discussed above. Current can be applied at low levels and/or with low duty cycle since the quantity of plated material in this process is very minute. Based on experiments using TMAH, approximately five gallons of 25% TMAH solution having a specific gravity of 1.0 to 1.1 Kg/L in a CoWP plating tool is sufficient to process approximately one thousand wafers per day for one year (assuming 300 working days per year. This rate of consumption of TMAH is equivalent to 57 moles of hydroxyl ions per year. The relationship of the applied current flow and the ions generated, based on Faraday's law can be summarized by:

m=η*(Q/F)*(M/z)

where

η is the electrolysis efficiency,

m is the mass of the substance formed (g),

Q is the total electric charge passed in the electrolysis,

Q=∫₀^{t}Idτ

I is the current (Amperes)

F=96.485 C mol⁻¹

M is the molar mass of the substance, and

z is the valency number of the electrons transferred per ion. In the practice of the invention, citric acid is a weak tribasic acid that dissociates in water and need not be electrolyzed.

Thus the time of application of current to the reaction vessel 200 in accordance with the invention, in seconds, can be calculated as 5.5×10⁶ divided by the applied current in Amperes. Assuming a ten Ampere power supply, current would only need to be applied for about one-half hour per day for processing a typical one-day throughput of one thousand wafers. Of course, the time of current application is directly proportional to the number of wafers processed.

In view of the foregoing, it is clearly seen that the method and apparatus in accordance with the invention provides a method and apparatus capable of continuous or periodic replenishment of materials in a chemical bath as those materials are consumed by a chemical reaction by integrating selective membrane technology with an electrochemical reaction process separate from but concurrent with the reaction consuming the materials and can do so in a fully controllable fashion. In particular, the invention provides for maintaining or adjusting pH of a chemical bath by injection of hydroxyl ions while isolating other ions from which the hydroxyl ions are dissociated.

While the invention has been described in terms of a single preferred embodiment, those skilled in the art will recognize that the invention can be practiced with modification within the spirit and scope of the appended claims.

Having thus described my invention, what I claim as new and desire to secure by Letters Patent is as follows:

1. A method of providing reactant ion species for a chemical reaction, said method comprising steps of
dissociating a compound into a first ion and a second ion in a solution in a first compartment of a replenishment vessel by passing a current through said solution,
splitting water into a proton and a hydroxyl ion in a membrane defining said first compartment and
passing said first ion or said hydroxyl ion to a second compartment of said reaction vessel through a selectively permeable membrane which isolates said second ion in said first compartment to form a chemical bath.

2. The method as recited in claim 1, wherein said chemical reaction is a plating reaction.

3. The method as recited in claim 2, wherein said plating operation is for a metal.

4. The method as recited in claim 3, wherein said metal is cobalt.

5. The method as recited in claim 1, wherein said first ion is a hydroxyl ion.

6. The method as recited in claim 1, wherein said second ion is a potassium or sodium ion.

7. The method as recited in claim 1, comprising further steps of
dissociating another compound into a third ion and a fourth ion in a further solution in a further compartment of said replenishment vessel by passing of said current through said solution and said further solution, and
passing said third ion from said further compartment to said second compartment of said replenishment vessel through a further selectively permeable membrane.

8. The method as recited in claim 7, wherein said third ion is a cobalt ion.

9. The method as recited in claim 1, wherein said chemical bath is recirculated through a tank.

10. The method as recited in claim 9, including a further step of
transferring said chemical bath from said tank to a reaction chamber.

11. Apparatus for replenishing a chemical bath comprising
an anode,
a cathode,
a selectively permeable membrane separating a cathode rinse compartment containing a first solution from a chemical bath compartment containing a chemical bath solution, and
a power supply for passing a current between said anode and said cathode through said first solution, said selectively permeable membrane and said chemical bath solution, said current causing electromigration of selected ions to said chemical bath solution while isolating other ions in said first solution from said chemical bath solution.

12. The apparatus as recited in claim 11, further comprising
a recirculation path for circulating said chemical bath solution to a reaction chamber and returning depleted chemical bath solution from said reaction chamber to said chemical bath compartment.

13. The apparatus as recited in claim 11, wherein said current dissociates water into a proton and a hydroxyl ion within said selectively permeable membrane.

14. The apparatus as recited in claim 11, wherein said selectively permeable membrane is a bipolar membrane.

15. The apparatus as recited in claim 14, wherein said bipolar membrane comprises
a cation exchange membrane layer, and
an anion exchange membrane layer.

16. The apparatus as recited in claim 11, further comprising
a cation exchange membrane separating said chemical bath compartment from a compartment containing said anode.

17. The apparatus as recited in claim 16, further comprising a source of cations in said compartment containing said anode, said cation exchange membrane being permeable to said cations.

18. The apparatus as recited in claim 17, wherein said cations are cations of a metal.

19. The apparatus as recited in claim 11, further comprising
sensors for monitoring solute concentrations in said chemical bath solution, and
controlling flow rate in said chemical bath compartment responsive to output of said sensors.

20. The apparatus as recited in claim 11, wherein said chemical bath compartment and said compartment containing said first solution are each divided into two or more compartments by bipolar membranes and cation exchange membranes.
